(19) United States
(12) Patent Application Publication
(10) Pub. No.: US 2024/0059919 A1
(43) Pub. Date: Feb. 22, 2024

(54) INK COMPOSITION, LAYER USING THE SAME, ELECTROPHORESIS DEVICE AND DISPLAY DEVICE COMPRISING THE SAME

(71) Applicant: Samsung Display Co., LTD., Yongin-sI (KR)

(72) Inventors: Minjun KIM, Yongin-si (KR); Kyuyoung KIM, Yongin-si (KR); MISUN KIM, Yongin-si (KR); BONGYONG KIM, Yongin-si (KR); YoungMin KIM, Yongin-si (KR); Janghyuk KIM, Yongin-si (KR); YOUNG WOO PARK, Yongin-si (KR); CHULJIN PARK, Yongin-si (KR); Heeje WOO, Yongin-si (KR); EUN SUN YU, Yongin-si (KR); Jinsuop YOUN, Yongin-si (KR); JEONGWOO LEE, Yongin-si (KR); HYUNMOO CHOI, Yongin-si (KR)

(21) Appl. No.: 18/364,025

(22) Filed: Aug. 2, 2023

(30) Foreign Application Priority Data
Aug. 3, 2022 (KR) 10-2022-0096845

(51) Int. Cl. C09D 11/38; C09D 11/36; G02F 1/16757; G02F 1/167

(52) U.S. Cl. CPC C09D 11/38; C09D 11/36; G02F 1/16757; G02F 1/167; G02F 2001/1678

(57) ABSTRACT

Disclosed are an ink composition, a layer manufactured using the ink composition, an electrophoresis device including the layer, and a display device, the ink composition including (A) a semiconductor nanorod including: a functional group represented by Chemical Formula 1; and (B) a solvent. In Chemical Formula 1, each substituent is as defined in the specification.

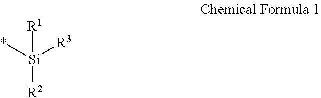

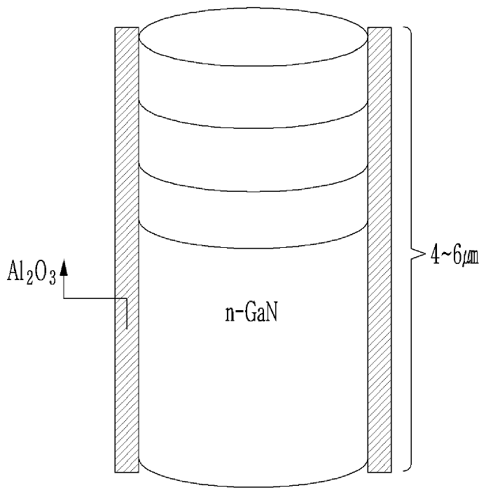

### CROSS-REFERENCE TO RELATED APPLICATION

This application claims priority to and the benefit of Korean Patent Application No. 10-2022-0096845 filed in the Korean Intellectual Property Office on Aug. 3, 2022, the entire contents of which are hereby incorporated by reference.

### BACKGROUND

### 1. Field

Embodiments of this disclosure relate to an ink composition, a layer using the same, and an electrophoresis device and a display device including the same.

### 2. Description of the Related Art

Light emitting diodes (LEDs) have been actively developed since 1992 when Nakamura and others from the Japanese company Nichia Corp. succeeded in fusing a high-quality single crystal GaN nitride semiconductor by applying a low temperature GaN compound buffer layer. An LED is a semiconductor device that converts electric signals into light having wavelengths in a desired region by using characteristics of a compound semiconductor, which has a structure in which an n-type semiconductor crystal in which a plurality of carriers are electrons and a p-type semiconductor crystal in which a plurality of carriers are holes are combined together with each other.

This LED semiconductor has high light conversion efficiency and thus consumes very little energy and has a semi-permanent life-span and also, is environmentally-friendly and thus is referred to as a revolution of light as a green material. Recently, high luminance red, orange, green, blue, and white LEDs have been developed with the development of compound semiconductor technology and are being applied in many fields such as traffic lights, mobile phones, car headlights, outdoor billboards, a liquid crystal display (LCD) back light unit (BLU), and indoor/outdoor lighting, which keeps being actively researched at home and abroad. For example, a GaN-based compound semiconductor having a wide bandgap is a material used to manufacture an LED semiconductor emitting light in green, blue, and ultraviolet (UV) regions, and because a blue LED device is used to manufacture a white LED device, substantial amounts of research is being conducted on blue LED devices.

Among these series of studies, studies using ultra-small LED devices having a nano or micro unit size are being actively conducted, and in addition, studies for utilizing these ultra-small LED devices in lighting and displays are being continuously made. In these studies, electrodes capable of applying power to the ultra-small LED devices, disposition of the electrodes for reducing a space occupied by the electrodes, a method of mounting the ultra-small LED devices on the disposed electrodes, and the like are continuously attracting attention.

Among these, the method of mounting the ultra-small LED devices on the disposed electrodes still has difficulties of disposing and mounting the ultra-small LED devices on the electrodes as intended due to size limitations of the ultra-small LED devices. The reason is that the ultra-small LED devices are nano-scale or micro-scale and thus may not be one by one disposed and mounted by hand on a target electrode region.

Recently, as the demand for the nano-scale ultra-small LED devices is increasing, an attempt to manufacture a nano-scale GaN-based or InGaN-based compound semiconductor into a rod has been made, but there is a problem that dispersion stability of a nanorod itself in a solvent (or a polymerizable compound) is greatly deteriorated or reduced. Until now, there has been no introduction of a technology of improving the dispersion stability of the semiconductor nanorods in a solvent (or a polymerizable compound). Therefore, research on a curable composition including semiconductor nanorods capable of improving the dispersion stability of semiconductor nanorods in a solvent (or polymerizable compound) and realizing a high dielectrophoresis rate is ongoing.

### SUMMARY

An embodiment of the present disclosure provides an ink composition having excellent electrophoretic characteristics of semiconductor nanorods.

Another embodiment provides a layer manufactured using the ink composition.

Another embodiment provides an electrophoresis device and a display device including the layer.

An embodiment provides an ink composition including: (A) a semiconductor nanorod including a functional group represented by Chemical Formula 1; and (B) a solvent.

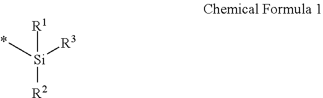

In Chemical Formula 1,

R¹ and R² are each independently hydrogen, a substituted or unsubstituted

C1 to C20 alkyl group, a substituted or unsubstituted C1 to C20 alkoxy group, or a substituted or unsubstituted C6 to C20 aryl group,

R³ is a substituted or unsubstituted C1 to C10 alkyl group, and * is a binding site to the semiconductor nanorod.

R¹ and R² may be identical to each other, and R³ may be different from R¹ and R².

R¹ and R² may each independently be a substituted or unsubstituted C1 to C20 alkoxy group.

R³ may be an unsubstituted C1 to C10 alkyl group.

R³ may be an unsubstituted C1 to C8 alkyl group.

R³ may be an unsubstituted C1 to C6 alkyl group.

R³ may be an unsubstituted C2 to C6 alkyl group.

The semiconductor nanorod may have a diameter of about 300 nm to about 900 nm.

The semiconductor nanorod may have a length of about 4 μm to about 6 μm.

The semiconductor nanorod may include a GaN-based compound, an InGaN-based compound, or a combination thereof.

The semiconductor nanorod may have a surface coated with a metal oxide.

The metal oxide may include alumina, silica, or a combination thereof.

The metal oxide may form a metal oxide coating layer on the semiconductor nanorod and the functional group represented by Chemical Formula 1 may be linked to the metal oxide coating layer on the surface of the semiconductor nanorod.

The semiconductor nanorod may be included in an amount of about 0.01 wt % to about 10 wt % based on the total amount of the ink composition.

The solvent may include a citrate-based compound.

The ink composition may further include malonic acid; 3-amino-1,2-propanediol; a silane-based coupling agent; a leveling agent; a fluorine-based surfactant; or a combination thereof.

The ink composition may be an ink composition for an electrophoresis device.

Another embodiment provides an ink composition including: (A) a semiconductor nanorod that is surface-modified with a surface-modifying material represented by Chemical Formula 2; and (B) a solvent.

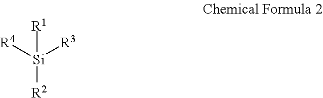

In Chemical Formula 2,

R¹ , R² , and R⁴ are each independently a substituted or unsubstituted C1 to C20 alkoxy group, and

R³ is a substituted or unsubstituted C1 to C10 alkyl group.

Another embodiment provides a layer manufactured using the ink composition.

Another embodiment provides an electrophoresis device including the layer.

Another embodiment provides a display device including the layer.

Other embodiments are included in the following detailed description.

The ink composition including the semiconductor nanorods may provide a curable composition having excellent electrophoretic characteristics (slow sedimentation rate and high dielectrophoresis rate).

### BRIEF DESCRIPTION OF THE DRAWINGS

The accompanying drawing, together with the specification, illustrates embodiments of the subject matter of the present disclosure, and, together with the description, serves to explain principles of embodiments of the subject matter of the present disclosure.

The accompanying drawing is an example of a cross-sectional view of a semiconductor nanorod used in a curable composition according to an embodiment.

### DETAILED DESCRIPTION

Hereinafter, embodiments of the present disclosure are described in more detail. However, these embodiments are just examples, the present disclosure is not limited thereto, and the present disclosure is defined by the scope of the appended claims and equivalents thereof.

As used herein, when a specific definition is not otherwise provided, “alkyl group” refers to a C1 to C20 alkyl group, “alkenyl group” refers to a C2 to C20 alkenyl group, “cycloalkenyl group” refers to a C3 to C20 cycloalkenyl group, “heterocycloalkenyl group” refers to a C3 to C20 heterocycloalkenyl group, “aryl group” refers to a C6 to C20 aryl group, “arylalkyl group” refers to a C6 to C20 arylalkyl group, “alkylene group” refers to a C1 to C20 alkylene group, “arylene group” refers to a C6 to C20 arylene group, “alkylarylene group” refers to a C6 to C20 alkylarylene group, “heteroarylene group” refers to a C3 to C20 heteroarylene group, and “alkoxylene group” refers to a C1 to C20 alkoxylene group.

As used herein, when a specific definition is not otherwise provided, “substituted” may refer to substitution with a halogen atom (F, Cl, Br, I), a hydroxy group, a C1 to C20 alkoxy group, a nitro group, a cyano group, an amine group, an imino group, an azido group, an amidino group, a hydrazino group, a hydrazono group, a carbonyl group, a carbamyl group, a thiol group, an ester group, an ether group, a carboxyl group or a salt thereof, a sulfonic acid group or a salt thereof, a phosphoric acid or a salt thereof, a C1 to C20 alkyl group, a C2 to C20 alkenyl group, a C2 to C20 alkynyl group, a C6 to C20 aryl group, a C3 to C20 cycloalkyl group, a C3 to C20 cycloalkenyl group, a C3 to C20 cycloalkynyl group, a C2 to C20 heterocycloalkyl group, a C2 to C20 heterocycloalkenyl group, a C2 to C20 heterocycloalkynyl group, a C3 to C20 heteroaryl group, or a combination thereof, instead of at least one hydrogen.

As used herein, when a specific definition is not otherwise provided, “hetero” may refer to one substituted with at least one hetero atom of N, O, S, and P, in a chemical formula.

As used herein, when a specific definition is not otherwise provided, “(meth)acrylate” refers to both “acrylate” and “methacrylate,” and “(meth)acryl-based” refers to both “acryl-based” and “methacryl-based.”

As used herein, when a specific definition is not otherwise provided, the term “combination” refers to mixing or copolymerization.

As used herein, unless a specific definition is otherwise provided, a hydrogen atom is bonded at the position when a chemical bond is not drawn where supposed to be given. For example, the chemical structures shown herein may omit hydrogen atoms for clarity, and those of ordinary skill in the art would readily understand that hydrogen atoms are present at the expected positions in the corresponding chemical compounds even when not shown in the chemical structures.

In this specification, a semiconductor nanorod refers to a rod-shaped semiconductor having a nano-sized diameter.

As used herein, when a specific definition is not otherwise provided, “*” indicates a point where the same or different atom or chemical formula is linked.

An ink composition according to an embodiment includes: (A) a semiconductor nanorod including a functional group represented by Chemical Formula 1; and (B) a solvent.

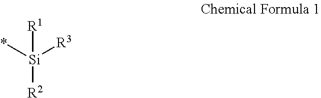

In Chemical Formula 1,

R¹ and R² are each independently hydrogen, a substituted or unsubstituted C1 to C20 alkyl group, a substituted or unsubstituted C1 to C20 alkoxy group, or a substituted or unsubstituted C6 to C20 aryl group,

R³ is a substituted or unsubstituted C1 to C10 alkyl group, and * is a binding site to the semiconductor nanorod (e.g., to any portion or feature of the semiconductor nanorod).

Recently, studies on various concepts having effects of improving energy efficiency and preventing or reducing a drop in efficiency of existing LEDs such as a micro LED, a mini LED, and the like have been actively conducted. Among them, an alignment (electrophoresis) of InGaN-based nanorod LEDs using an electric field has drawn attention as a method of dramatically reducing complex and expensive process costs of the micro LED, the mini LED, and the like.

However, organic solvents (propylene glycol methyl ether acetate (PGMEA), gamma butyrolactone (GBL), propylene glycol methyl ether (PGME), ethyl acetate, isopropyl alcohol (IPA), and/or the like) generally used in a display and an electronic material have low viscosity and thus inorganic nanorod particles having high density may be sedimented or precipitated too fast and thus aggregated, and in addition, may be quickly volatilized and thus may deteriorate or reduce alignment characteristics during the solvent drying after the dielectrophoresis. Previously, in order to solve the above problem, efforts to change a composition of the solvent and the like have been made, but unlike the previous approach, the present inventors have confirmed that semiconductor nanorods instead of the solvent are surface-treated to secure excellent dispersion stability in an organic solvent and the like and improve a sedimentation or precipitation rate and dielectrophoretic alignment characteristics, thereby providing embodiments of the present disclosure.

For example, the electrophoresis of the semiconductor nanorods may be achieved by inkjetting and/or slit-coating a semiconductor nanorod dispersion, but the dispersion stability of the nanorods is an important or essential parameter for large-area coating. In other words, an interaction between “hydrophilicity or hydrophobicity of the solvent in which the semiconductor nanorods are dispersed” and “solubility of the semiconductor nanorod surface” helps the dispersion stability of the semiconductor nanorods. Herein, the dispersion stability is an important property that determines or affects processibility such as the sedimentation rate of the semiconductor nanorods, aggregation between the semiconductor nanorods, etc. during the dielectrophoresis. According to an embodiment of the present disclosure, a solubility interaction between the organic solvent in which the semiconductor nanorods are dispersed and a ligand may be increased or maximized to increase the dispersion stability between the semiconductor nanorods during the dielectrophoresis and to lower the sedimentation rate (e.g., precipitation rate) of the semiconductor nanorods, thereby ultimately improving inkjetting processability and alignment characteristics of an ink composition including the semiconductors nanorods.

Hereinafter, relevant components of embodiments of the ink composition are described in more detail.

### (A) Semiconductor Nanorod

The higher the dispersion stability of the ink composition including semiconductor nanorods and a solvent, the better large area inkjetting and dielectrophoretic processability. For example, improving the dispersion stability of the ink composition improves the inkjetting and dielectrophoretic processability of the ink composition over a large area. According to an embodiment, in order to prepare a semiconductor nanorod inkjetting solution applicable to a large display panel, the dispersion stability may be increased or maximized by binding a ligand having a set or specific structure with a coating layer on the semiconductor nanorod surface or an insulation layer (Al₂O₃ and/or SiOₓ) and improving or optimizing an interaction between semiconductor nanorod and the solvent.

Properties of the ink composition containing the semiconductor nanorods may be determined depending on whether or not the semiconductor nanorods are surface-treated with a ligand. When the surface treatment is performed by applying hydrophobic ligands, dispersibility and dielectrophoresis characteristics of the ink composition may be improved, compared with an ink composition including nonsurface-treated semiconductor nanorods. For example, among the hydrophobic ligands applied during the surface treatment, the properties may vary depending on a length of an alkyl group constituting the ligands, and the present inventors, after repeating numerous experiments, have developed a ligand structure with an improved or optimal length, which brings about excellent properties, thereby providing embodiments of the present disclosure.

The surface treatment of the semiconductor nanorods, for example, the surface treatment of the semiconductor nanorods by using the ligand represented by Chemical Formula 1 (surface-modifying material represented by Chemical Formula 2) may increase dispersion stability in the organic solvent and significantly improve a sedimentation rate (e.g., a precipitation rate) and dielectrophoretic alignment characteristics.

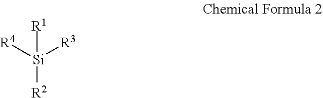

In Chemical Formula 2,

R¹ , R² , and R⁴ are each independently a substituted or unsubstituted C1 to C20 alkoxy group, and

R³ is a substituted or unsubstituted C1 to C10 alkyl group. In the surface modification of the semiconductor nanorods with the surface-modifying material represented by Chemical Formula 2, R⁴ may react to bind the surface-modifying material represented by Chemical Formula 2 to any feature or portion of the semiconductor nanorod.

For example, in Chemical Formula 1, R¹ and R² may be identical to each other, and R³ may be different from R¹ and R².

For example, in Chemical Formula 2, R¹ , R² , and R⁴ may be the same as each other, and R³ may be different from R¹ and R².

For example, in Chemical Formula 1, R¹ and R² may each independently be a substituted or unsubstituted C1 to C20 alkoxy group.

For example, in Chemical Formula 2, R¹ , R² , and R⁴ may each independently be a substituted or unsubstituted C1 to C20 alkoxy group.

For example, in Chemical Formula 1, R¹ and R² may each independently represent a substituted or unsubstituted C1 to C20 alkoxy group, and R³ may be an unsubstituted C1 to C10 alkyl group.

For example, in Chemical Formula 2, R¹ , R² , and R⁴ may each independently be a substituted or unsubstituted C1 to C20 alkoxy group, and R³ may be an unsubstituted C1 to C10 alkyl group.

For example, in Chemical Formula 1, R¹ and R² may each independently represent a substituted or unsubstituted C1 to C20 alkoxy group, and R³ may be an unsubstituted C1 to C8 alkyl group.

For example, in Chemical Formula 2, R¹ , R² , and R⁴ may each independently be a substituted or unsubstituted C1 to C20 alkoxy group, and R³ may be an unsubstituted C1 to C8 alkyl group.

For example, in Chemical Formula 1, R¹ and R² may each independently represent a substituted or unsubstituted C1 to C20 alkoxy group, and R³ may be an unsubstituted C1 to C6 alkyl group.

For example, in Chemical Formula 2, R¹ , R² , and R⁴ may each independently be a substituted or unsubstituted C1 to C20 alkoxy group, and R³ may be an unsubstituted C1 to C6 alkyl group.

For example, in Chemical Formula 1, R¹ and R² may each independently represent a substituted or unsubstituted C1 to C20 alkoxy group, and R³ may be an unsubstituted C2 to C8 alkyl group.

For example, in Chemical Formula 2, R¹ , R² , and R⁴ may each independently be a substituted or unsubstituted C1 to C20 alkoxy group, and R³ may be an unsubstituted C2 to C8 alkyl group.

For example, in Chemical Formula 1, R¹ and R² may each independently be a substituted or unsubstituted C1 to C20 alkoxy group, and R³ may be an unsubstituted C2 to C6 alkyl group.

For example, in Chemical Formula 2, R¹ , R² , and R⁴ may each independently be a substituted or unsubstituted C1 to C20 alkoxy group, and R³ may be an unsubstituted C2 to C6 alkyl group.

According to embodiments of the present disclosure, by controlling the length and substituent of the alkyl group R³ in the functional group represented by Chemical Formula 1 (or the alkyl group R³ in the surface-modifying material represented by Chemical Formula 2), the sedimentation rate (e.g., precipitation rate) and dielectrophoretic alignment characteristics can be greatly improved.

The semiconductor nanorod may include a GaN-based compound, an InGaN-based compound, or a combination thereof, and may have a surface coated with a metal oxide.

For the dispersion stability of the semiconductor nanorod ink solution (semiconductor nanorod+solvent), a time of about 3 hours was previously generally achieved, which is an extremely insufficient time to perform a large-area inkjet process. However, by coating the surface of the semiconductor nanorod with a metal oxide containing alumina, silica, or a combination thereof to form a coating layer and/or an insulating layer (Al₂O₃ and/or SiOₓ), compatibility with a solvent further described herein below can be increased or maximized.

For example, the coating layer and/or insulating layer coated with the metal oxide may have a thickness of about 40 nm to about 60 nm.

For example, the functional group represented by Chemical Formula 1 may be linked to a metal oxide coating layer and/or an insulating layer on the surface of the semiconductor nanorod. In this case, because the compatibility with the solvent further described herein below becomes very excellent, both the dispersion stability of the semiconductor nanorods and the dielectrophoretic characteristics of the ink composition may be greatly improved.

The semiconductor nanorod may include an n-type confinement layer and a p-type confinement layer, and a multiquantum well active portion (MQW active region; multiquantum well active region) may be between the n-type confinement layer and the p-type confinement layer.

For example, the semiconductor nanorod may have a diameter of about 300 nm to about 900 nm, or, for example, about 600 nm to about 700 nm.

For example, the semiconductor nanorod may have a length of about 4 μm to about 6 μm.

For example, when the semiconductor nanorod includes an alumina insulating layer, it may have a density of about 5 g/cm³ to about 6 g/cm³.

For example, the semiconductor nanorod may have a mass of about 1×10⁻¹³ g to about 1×10⁻¹¹ g.

When the semiconductor nanorod have the above diameter, length, density, and type (or kind), surface coating of the metal oxide may be facilitated, and dispersion stability of the semiconductor nanorods may be increased or maximized.

The semiconductor nanorod may be included in the ink composition in an amount of about 0.01 wt % to about 10 wt %, for example, about 0.01 wt % to about 5 wt %, based on the total amount of the ink composition. In some embodiments, the semiconductor nanorods may be included in the ink composition in an amount of about 0.01 parts by weight to about 0.5 parts by weight, or, for example, about 0.01 parts by weight to about 0.1 parts by weight, based on 100 parts by weight of the solvent in the ink composition. When the semiconductor nanorod is included within the above range, dispersibility in the ink is good, and the manufactured pattern may have excellent luminance.

### (B) Solvent

Organic solvents such as propylene glycol monomethyl ether acetate (PGMEA), γ-butyrolactone (GBL), polyethylene glycol methyl ether (PGME), ethylacetate, isopropyl alcohol (IPA), and/or the like, which have been used in existing displays and electron materials have such low viscosity that inorganic material nanorod particles having high density are sedimented or precipitated too quickly, thereby resulting in unsatisfactory dielectrophoretic characteristics. According to an embodiment, the above problems can be solved through surface treatment of the semiconductor nanorods, but if there is a solvent capable of imparting sedimentation stability to the semiconductor nanorods, it may be more suitable or desirable to use such a solvent.

For example, the solvent may include a citrate-based compound, but is not necessarily limited thereto.

For example, the solvent may have a viscosity of greater than or equal to about 3 cps at 50° C.

For example, the solvent may include a compound represented by Chemical

Formula 3 and/or a compound represented by Chemical Formula 4.

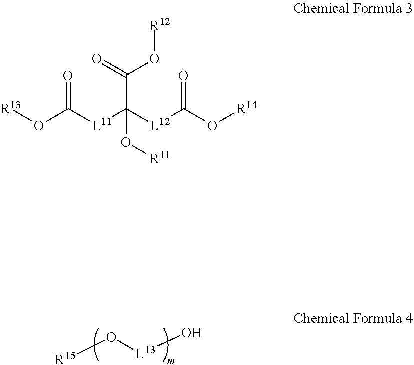

In Chemical Formula 3 and Chemical Formula 4,

[symbol]

R¹¹ is a hydrogen atom or *—C(═O)R′ (wherein R′ is a hydrogen atom or a substituted or unsubstituted C1 to C10 alkyl group),

R¹² to R¹⁴ are each independently a substituted or unsubstituted C2 to C20 alkyl group,

R¹⁵ is a substituted or unsubstituted C1 to C20 alkyl group or a C6 to C20 aryl group that is substituted or unsubstituted with a C2 to C10 alkoxy group,

L¹¹ to L¹³ are each independently a substituted or unsubstituted C1 to C20 alkylene group, and

m is an integer from 1 to 20.

For example, the compound represented by Chemical Formula 3 may include a compound represented by Chemical Formula 3-1 and/or a compound represented by Chemical Formula 3-2.

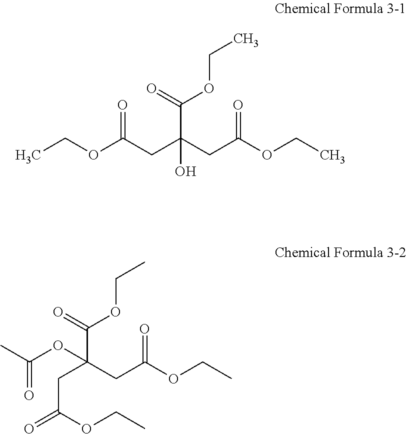

For example, the compound represented by Chemical Formula 4 may include a compound represented by any one selected from Chemical Formula 4-1 to Chemical Formula 4-4.

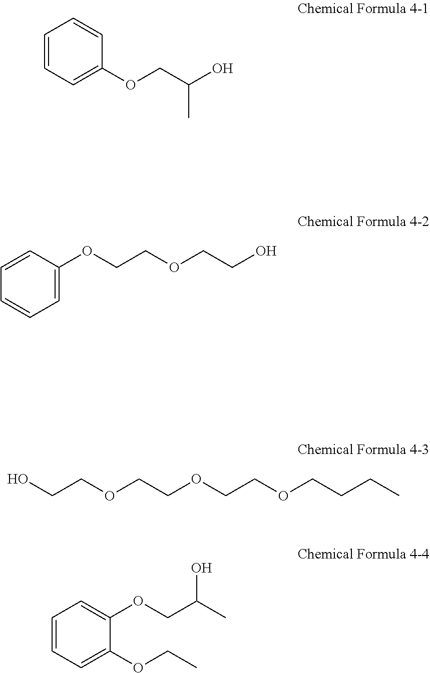

The solvent may be included in the ink composition in an amount of about 5 wt % to about 99.99 wt %, for example, about 20 wt % to about 99.95 wt %, or, for example, about 90 wt % to about 99.99 wt %, based on the total amount of the ink composition.

### Polymerizable Monomer

The ink composition according to an embodiment may further include a polymerizable compound, if necessary. The polymerizable compound may be used by mixing together monomers and/or oligomers generally used in the art for curable compositions.

For example, the polymerizable compound may be a polymerizable monomer having a carbon-carbon double bond at a terminal end.

For example, the polymerizable compound may be a polymerizable monomer having at least one functional group represented by Chemical Formula A-1 and/or a functional group represented by Chemical Formula A-2 at a terminal end.

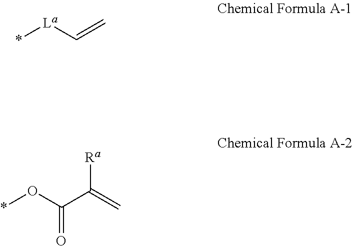

In Chemical Formula A-1 and Chemical Formula A-2,

L^{a} is a substituted or unsubstituted C1 to C20 alkylene group,

R^{a} is a hydrogen atom or a substituted or unsubstituted C1 to C20 alkyl group.

The polymerizable compound includes at least one carbon-carbon double bond at a terminal end, for example, a functional group represented by Chemical Formula A-1 and/or a functional group represented by Chemical Formula A-2, thereby forming a crosslinked structure with the surface-modifying compound. The crosslinked body thus formed may further enhance dispersion stability of the semiconductor nanorods by further doubling a type (or kind) of steric hindrance effect.

For example, the polymerizable compound including at least one functional group represented by Chemical Formula A-1 at a terminal end may be divinyl benzene, triallyl cyanurate, triallyl isocyanurate, triallyl trimellitate, triallyl phosphate, triallyl phosphite, triallyl triazine, diallyl phthalate, or a combination thereof, but is not necessarily limited thereto.

For example, the polymerizable compound including at least one functional group represented by Chemical Formula A-2 at a terminal end may be ethylene glycol diacrylate, triethylene glycol diacrylate, 1,4-butanediol diacrylate, 1,6-hexane diol diacrylate, neopentyl glycol diacrylate, pentaerythritol diacrylate, pentaerythritol triacrylate, dipentaerythritol diacrylate, dipentaerythritol triacrylate, dipentaerythritol pentaacrylate, pentaerythritol hexaacrylate, bisphenol A diacrylate, trimethylolpropane triacrylate, novolac epoxy acrylate, ethylene glycol dimethacrylate, diethylene glycol dimethacrylate, triethylene glycol dimethacrylate, propylene glycol dimethacrylate, 1,4-butanediol dimethacrylate, 1,6-hexanediol dimethacrylate, polyfunctional epoxy (meth)acrylate, polyfunctional urethane (meth)acrylate, KAYARAD DPCA-20, KAYARAD DPCA-30, KAYARAD DPCA-60, KAYARAD DPCA-120, and/or KAYARAD DPEA-12 (where the KAYARAD family of compounds are available from Nippon Chemical Co., Ltd.), or a combination thereof, but is not necessarily limited thereto.

The polymerizable compound may be used after being treated with an acid anhydride to impart better developability.

### Polymerization Initiator

The ink composition according to an embodiment may further include a polymerization initiator, for example, a photopolymerization initiator, a thermal polymerization initiator, or a combination thereof, as needed.

The photopolymerization initiator may be any suitable generally-used initiator for a curable composition and may be, for example, an acetophenone-based compound, a benzophenone-based compound, a thioxanthone-based compound, a benzoin-based compound, a triazine-based compound, an oxime-based compound, an aminoketone-based compound, and/or the like, but is not necessarily limited thereto.

Examples of the acetophenone-based compound may be 2,2′-diethoxy acetophenone, 2,2′-dibutoxy acetophenone, 2-hydroxy-2-methylpropinophenone, p-t-butyltrichloro acetophenone, p-t-butyldichloro acetophenone, 4-chloro acetophenone, 2,2′-dichloro-4-phenoxy acetophenone, 2-methyl-1-(4-(methylthio)phenyl)-2-morpholinopropan-1-one, 2-benzyl-2-dimethylamino-1-(4-morpholinophenyl)-butan-1-one, and the like.

Examples of the benzophenone-based compound may be benzophenone, benzoyl benzoate, benzoyl methyl benzoate, 4-phenyl benzophenone, hydroxybenzophenone, acrylated benzophenone, 4,4′-bis(dimethyl amino)benzophenone, 4,4′-bis(diethylamino)benzophenone, 4,4′-dimethylaminobenzophenone, 4,4′-dichlorobenzophenone, 3,3′-dimethyl-2-methoxybenzophenone, and the like.

Examples of the thioxanthone-based compound may be thioxanthone, 2-methylthioxanthone, isopropyl thioxanthone, 2,4-diethyl thioxanthone, 2,4-diisopropyl thioxanthone, 2-chlorothioxanthone, and the like.

Examples of the benzoin-based compound may be benzoin, benzoin methyl ether, benzoin ethyl ether, benzoin isopropyl ether, benzoin isobutyl ether, benzyldimethylketal, and the like.

Examples of the triazine-based compound may be 2,4,6-trichloro-s-triazine, 2-phenyl-4,6-bis(trichloromethyl)-s-triazine, 2-(3′,4′-dimethoxystyryl)-4,6-bis(trichloromethyl)-s-triazine, 2-(4′-methoxynaphthyl)-4,6-bis(trichloromethyl)-s-triazine, 2-(p-methoxyphenyl)-4,6-bis(trichloromethyl)-s-triazine, 2-(p-tolyl)-4,6-bis(trichloro methyl)-s-triazine, 2-biphenyl-4,6-bis(trichloro methyl)-s-triazine, bis(trichloromethyl)-6-styryl-s-triazine, 2-(naphthol -yl)-4,6-bis(trichloromethyl)-s-triazine, 2-(4-methoxynaphtho1-yl)-4,6-bis(trichloromethyl)-s-triazine, 2-4-bis(trichloromethyl)-6-piperonyl-s-triazine, 2-4-bis(trichloromethyl)-6-(4-methoxystyryl)-s-triazine, and the like.

Examples of the oxime-based compound may be an O-acyloxime-based compound such as, for example, 2-(O-benzoyloxime)-1-[4-(phenylthio)phenyl]-1,2-octanedione, 1-(O-acetyloxime)-1-[9-ethyl-6-(2-methylbenzoyl)-9H-carbazol-3-yl]ethanone, O-ethoxycarbonyl-α-oxyamino-1-phenylpropan-1-one, and the like. Further examples of the 0-acyloxime-based compound may be 1,2-octandione, 2-dimethylamino-2-(4-methylbenzyl)-1-(4-morpholin-4-yl-phenyl)-butan-1-one, 1-(4-phenylsulfanyl phenyl)-butane-1,2-dione-2-oxime-O-benzoate, 1-(4-phenylsulfanyl phenyl)-octane-1,2-dione-2-oxime-O-benzoate, 1-(4-phenylsulfanyl phenyl)-octan-1-oneoxime-O-acetate, 1-(4-phenylsulfanyl phenyl)-butan-1-oneoxime-O-acetate, and the like.

Examples of the aminoketone-based compound may be 2-benzyl-2-dimethylamino-1-(4-morpholinophenyl)-butanone-1, and the like.

The photopolymerization initiator may further include a carbazole-based compound, a diketone-based compound, a sulfonium borate-based compound, a diazo-based compound, an imidazole-based compound, a biimidazole-based compound, and/or the like besides the above-described compounds.

The photopolymerization initiator may be used together with a photosensitizer capable of causing a chemical reaction by absorbing light and becoming excited (being promoted to an excited state) and then transferring its energy.

Examples of the photosensitizer may be tetraethylene glycol bis-3-mercapto propionate, pentaerythritol tetrakis-3-mercapto propionate, dipentaerythritol tetrakis-3-mercapto propionate, and the like.

Examples of the thermal polymerization initiator may include peroxide, specifically benzoyl peroxide, dibenzoyl peroxide, lauryl peroxide, dilauryl peroxide, di-tert-butyl peroxide, cyclohexane peroxide, methyl ethyl ketone peroxide, oxides, hydroperoxide (e.g., tert-butyl hydroperoxide, cumene hydroperoxide, etc.), dicyclohexyl peroxydicarbonate, 2,2-azo-bis(isobutyronitrile), t-butyl perbenzoate, 2,2′-azobis-2-methylpropionitrile, etc., but it is not necessarily limited thereto, and any suitable one generally used in the art may be used.

The polymerization initiator may be included in the ink composition in an amount of about 1 wt % to about 5 wt %, or, for example, about 2 wt % to about 4 wt %, based on the total amount of solid components constituting the ink composition. When the polymerization initiator is included within the above range, excellent reliability may be obtained due to suitable or sufficient curing during exposure and/or thermal curing.

### Other Additives

The curable composition according to an embodiment may further include a polymerization inhibitor including a hydroquinone-based compound, a catechol-based compound, or a combination thereof. As the ink composition according to an embodiment further includes the hydroquinone-based compound, the catechol-based compound, or a combination thereof, crosslinking at room temperature may be prevented or reduced during exposure after printing (coating) the ink composition.

For example, the hydroquinone-based compound, the catechol-based compound, or the combination thereof may be hydroquinone, methyl hydroquinone, methoxyhydroquinone, t-butyl hydroquinone, 2,5-di-t-butyl hydroquinone, 2,5-bis(1,1-dimethylbutyl) hydroquinone, 2,5-bis (1,1,3,3-tetramethylbutyl) hydroquinone, catechol, t-butyl catechol, 4-methoxyphenol, pyrogallol, 2,6-di-t-butyl-4-methylphenol, 2-naphthol, tris(N-hydroxy-N-nitrosophenylaminato-O,O′)aluminum, or a combination thereof, but are not necessarily limited thereto.

The hydroquinone-based compound, catechol-based compound, or combination thereof may be used in a form of dispersion, and the polymerization inhibitor in a form of the dispersion may be included in the ink composition in an amount of about 0.001 wt % to about 1 wt %, or, for example, about 0.01 wt % to about 0.1 wt % based on the total amount of the ink composition. When the polymerization inhibitor is included within the above ranges, passage of time at room temperature (e.g., the above-described issues with dispersion stability) may be solved and concurrently (e.g., simultaneously), sensitivity deterioration and surface delamination phenomenon may be inhibited or reduced.

The ink composition according to an embodiment may include: malonic acid; 3-amino-1,2-propanediol; a silane-based coupling agent; a leveling agent; a fluorine-based surfactant; or a combination thereof, in addition to the polymerization inhibitor.

For example, the ink composition may further include a silane-based coupling agent having a reactive substituent such as a vinyl group, a carboxyl group, a methacryloxy group, an isocyanate group, an epoxy group and/or the like in order to improve close contacting properties with a substrate.

Examples of the silane-based coupling agent may be trimethoxysilyl benzoic acid, γ-methacryl oxypropyl trimethoxysilane, vinyl triacetoxysilane, vinyl trimethoxysilane, γ-isocyanate propyl triethoxysilane, γ-glycidoxy propyl trimethoxysilane, β-epoxycyclohexypethyltrimethoxysilane, and the like, and these may be used alone or in a mixture of two or more.

The silane-based coupling agent may be used in the ink composition in an amount of about 0.01 parts by weight to about 10 parts by weight based on 100 parts by weight of the ink composition. When the silane-based coupling agent is included within the above range, close contacting properties, storage capability, and the like are improved.

In addition, the ink composition may further include a surfactant, such as a fluorine-based surfactant, to improve coating properties and prevent or reduce defect formation, if necessary or desired.

Examples of the fluorine-based surfactant may be BM-1000®, BM-1100®, and the like of BM Chemie Inc.; MEGAFACE F 142D®, MEGAFACE F 172®, MEGAFACE F 173®, MEGAFACE F 183 ®, and the like of Dainippon Ink Kagaku Kogyo Co., Ltd.; FLUORAD FC-135®, FLUORAD FC-170C®, FLUORAD FC-430®, FLUORAD FC-431®, and the like of Sumitomo 3M Co., Ltd.; SURFLON S-112®, SURFLON S-113®, SURFLON S-131®, SURFLON S-141®, SURFLON S-145®, and the like of ASAHI Glass Co., Ltd.; SH-28PA®, SH-190®, SH-193®, SZ-6032®, SF-8428®, and the like of Toray Silicone Co., Ltd.; F-482, F-484, F-478, F-554, and the like of DIC Co., Ltd.

The fluorine-based surfactant may be included in the ink composition in an amount of about 0.001 parts by weight to about 5 parts by weight based on 100 parts by weight of the ink composition. When the fluorine-based surfactant is included within the above range, coating uniformity is secured, stains do not occur, and wettability to a glass substrate is excellent.

In addition, the ink composition may further include other additives such as an antioxidant, a stabilizer, and/or the like in a set or predetermined amount, unless properties are undesirably deteriorated.

Another embodiment provides a layer using an ink composition.

Another embodiment may provide an electrophoresis device and/or a display device including the layer.

Hereinafter, embodiments of the present disclosure are illustrated in more detail with reference to examples. These examples, however, are not in any sense to be interpreted as limiting the scope of the present disclosure.

### Preparation of Curable Composition

### Example 1

40 ml of hexyl trimethoxysilane (cas#: 3069-19-0, HSCA, 1.5 mM solution in dodecane), a ligand, is reacted on a nanorod-patterned GaN wafer (4 inches) at room temperature for 15 hours. After the reaction, the wafer obtained therefrom is dipped in 50 ml of acetone for 5 minutes to remove the excess ligand, and the wafer surface is additionally rinsed by using 40 ml of acetone. The washed wafer is put together with 35 ml of GBL in a 27 kW bath type sonicator and then sonicated for 5 minutes to separate rods from the wafer surface. The separated rods are put in a FALCON tube for centrifugation, and 10 ml of GBL is added thereto to additionally wash the rods on the bath surface. After discarding a supernatant therefrom through centrifugation at 4000 rpm for 10 minutes, precipitates therefrom are redispersed in 40 ml of acetone and passed through a 10 pm mesh filter to filter out foreign matters. After additional centrifugation (4000 rpm, 10 minutes), the precipitates are dried in a dry oven (100° C., 1 hour) and then, weighed and dispersed to be 0.05 w/w % in triethyl 2-acetyl citrate (TEC-Ac), thereby preparing an ink composition.

### Example 2

An ink composition is prepared in the same manner as in Example 1 except that octyl trimethoxysilane (cas#: 3069-40-7, OD-CA, 1.5 mM solution in dodecane) is used instead of the hexyl trimethoxysilane as the ligand.

### Example 3

An ink composition is prepared in the same manner as in Example 1 except that ethyl trimethoxysilane (cas#: 5314-55-6, OD-CA, 1.5 mM solution in dodecane) is used instead of the hexyl trimethoxysilane as the ligand.

### Comparative Example 1

An ink composition is prepared in the same manner as in Example 1 except that the ligand is not used.

The ligands used in Examples 1 to 3 have each following structure, which is shown in Table 1.

TABLE 1

| | Ligand structure |
|---|---|
| Example 1 | 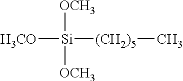 |
| Example 2 | 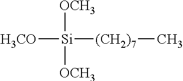 |
| Example 3 | 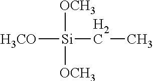 |

### Evaluation

The ink compositions according to Examples 1 to 3 and Comparative Example 1 are measured with respect to a sedimentation rate by using Turbiscan and then evaluated with respect to the sedimentation rate and dielectrophoretic characteristics by using a backscattering (BS) reduction rate 8 hours later after the measurement, and TSI (Turbiscan stability index) in Turbiscan, etc., and the results are shown in Table 2

TABLE 2

| | Example | Example | Example | Comparative |
|---|---|---|---|---|
| | 1 | 2 | 3 | Example 1 |
| Sedimentation rate | 0.302 | 0.361 | 0.347 | 0.459 |
| (mm/h) | | | | |
| Dielectrophoretic | 98 | 80 | 80 | 70 |
| characteristics (%) | | | | |

Referring to Table 2, the ink compositions including semiconductor nanorods surface-modified with a hydrophobic ligand in which a length of an alkyl group and a substituent are controlled (Examples 1 to 3), compared with the composition of Comparative Example 1 (which did not include a ligand), exhibit an improved sedimentation rate and also, excellent dielectrophoretic characteristics.

While the subject matter of this disclosure has been described in connection with what is presently considered to be practical example embodiments, it is to be understood that the present disclosure is not limited to the disclosed embodiments, but, on the contrary, is intended to cover various modifications and equivalent arrangements included within the spirit and scope of the appended claims, and equivalents thereof.

What is claimed is:

1. An ink composition, comprising:
(A) a semiconductor nanorod comprising a functional group represented by Chemical Formula 1; and
(B) a solvent: 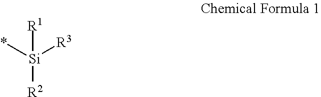
wherein, in Chemical Formula 1,
R¹ and R² are each independently hydrogen, a substituted or unsubstituted C1 to C20 alkyl group, a substituted or unsubstituted C1 to C20 alkoxy group, or a substituted or unsubstituted C6 to C20 aryl group, and
R³ is a substituted or unsubstituted C1 to C10 alkyl group.

2. The ink composition of claim 1, wherein:
R¹ and R² are the same, and
R³ is different from R¹ and R².

3. The ink composition of claim 1, wherein:
R¹ and R² are each independently a substituted or unsubstituted C1 to C20 alkoxy group.

4. The ink composition of claim 3, wherein:
R³ is an unsubstituted C1 to C10 alkyl group.

5. The ink composition of claim 4, wherein:
R³ is an unsubstituted C1 to C8 alkyl group.

6. The ink composition of claim 4, wherein:
R³ is an unsubstituted C1 to C6 alkyl group.

7. The ink composition of claim 4, wherein:
R³ is an unsubstituted C2 to C6 alkyl group.

8. The ink composition of claim 1, wherein:
the semiconductor nanorod has a diameter of about 300 nm to about 900 nm.

9. The ink composition of claim 1, wherein:
the semiconductor nanorod has a length of about 4 μm to about 6 μm.

10. The ink composition of claim 1, wherein:
the semiconductor nanorod comprising a GaN-based compound, an InGaN-based compound, or a combination thereof.

11. The ink composition of claim 1, wherein:
the semiconductor nanorod has a surface coated with a metal oxide.

12. The ink composition of claim 11, wherein:
the metal oxide includes alumina, silica, or a combination thereof.

13. The ink composition of claim 11, wherein:
the metal oxide forms a metal oxide coating layer on the semiconductor nanorod and the functional group represented by Chemical Formula 1 is linked to the metal oxide coating layer.

14. The ink composition of claim 1, wherein:
the semiconductor nanorod is included in an amount of about 0.01 wt % to about 10 wt % based on the total amount of the ink composition.

15. The ink composition of claim 1, wherein:
the solvent comprises a citrate-based compound.

16. The ink composition of claim 1, wherein:
the ink composition further comprises: malonic acid; 3-amino-1,2-propanediol; a silane-based coupling agent; a leveling agent; a fluorine-based surfactant; or a combination thereof.

17. The ink composition of claim 1, wherein:
the ink composition is an ink composition for an electrophoresis device.

18. An ink composition, comprising:
(A) a semiconductor nanorod that is surface-modified with a surface-modifying material represented by Chemical Formula 2; and
(B) a solvent: 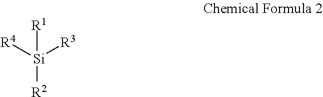
wherein, in Chemical Formula 2,
R¹ , R² , and R⁴ are each independently a substituted or unsubstituted C1 to C20 alkoxy group, and
R³ is a substituted or unsubstituted C1 to C10 alkyl group.

19. A layer manufactured using the ink composition of claim 1.

20. An electrophoresis device comprising the layer of claim 19.

21. A display device comprising the layer of claim 19.
